(19) United States
(12) Patent Application Publication
(10) Pub. No.: US 2026/0342356 A1
(43) Pub. Date: Oct. 29, 2026

(54) TERNARY ENCODING AND DECODING

(71) Applicant: GSI Technology Inc., Sunnyvale, CA (US)

(72) Inventors: Avidan AKERIB, Tel Aviv (IL); Mark WRIGHT, Cupertino, CA (US)

(21) Appl. No.: 19/632,325

(22) Filed: Mar. 29, 2026

Related U.S. Application Data
(60) Provisional application No. 63/793,650, filed on Apr. 24, 2025.
(60) Provisional application No. 63/839,047, filed on Jul. 6, 2025.
(60) Provisional application No. 63/861,030, filed on Aug. 10, 2025.
(60) Provisional application No. 63/965,521, filed on Jan. 22, 2026.

(51) Int. Cl. H03M 7/30; G06F 15/80

(52) U.S. Cl. CPC H03M 7/3066; G06F 15/8038; H03M 7/6011

(57) ABSTRACT

A method and system for encoding a set of ternary values, each selected from {−1, 0, +1}, into an encoded integer having a predefined number of bits involves mapping the ternary values to a set of mapped integers, where each mapped integer is a non-negative integer in the set {0, 1, 2}. The method computes a weighted sum of the mapped integers using powers of 3, where a final result fits within a predefined byte range. A corresponding method and system for decoding the encoded binary integer into a set of ternary values involves multiplying the encoded integer by a predetermined constant, right-shifting the result to produce a quotient, and iteratively computing a modulo 3 remainder. The methods can be implemented on associative processing units (APUs). An alternative embodiment has a mapping scheme which preserves the zero value and thus, enables a fast path for all-zero data blocks.

### CROSS REFERENCE TO RELATED APPLICATIONS

This application claims priority from U.S. provisional patent applications 63/793,650, filed Apr. 24, 2025, 63/839,047, filed Jul. 6, 2025, 63/861,030, filed Aug. 10, 2025, and 63/965,521, filed Jan. 22, 2026, all of which are incorporated herein by reference.

### FIELD OF THE INVENTION

The present invention relates generally to digital data processing, and in particular to methods and systems for the encoding and decoding of ternary data.

### BACKGROUND OF THE INVENTION

In various fields of computing, such as artificial intelligence (AI) and digital signal processing, system performance may be enhanced by utilizing ternary values. In many cases there is over-precision of data used in processing due to traditional input sequences or sensor front end systems. This over-precision is being addressed in the field by computationally reducing bits used for certain representations. A ternary value, or “trit”, may represent one of three states, for example, {−1, 0, +1}. The use of ternary values may reduce the computational precision required for certain operations, which may in turn lower power consumption and memory requirements, particularly in resource-constrained devices like embedded systems, autonomous systems, and mobile hardware.

Conventional computing systems, however, are based on binary logic and do not natively support three-state data. This leads to inefficiencies in both storage and processing.

Reference is now made to FIGS. 1A, 1B, and 1C, which are schematic illustrations of data representations in the prior art. FIG. 1A illustrates a standard 8-bit binary value 110, with bits that are either 1 or 0. An 8-bit “byte” is the fundamental data unit in most computer systems.

FIG. 1B illustrates a single ternary value 120, having the values (1, −1, 1, 0, 0), which represents the decimal value 63. A common prior art method for storing ternary value 120 is shown in FIG. 1C, where each ternary value is represented with two bits, where (1,1) represents a ternary value of 1, (0,0) represents a ternary value of −1, and (0,1) or (1,0) represents a ternary value of 0. Since two bits may represent four distinct states, using them to store only three states is inherently inefficient and results in wasted memory. Thus, ternary value 120 is represented as 10100/10111 in the two bit representation 122.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIGS. 1A-1C are schematic illustrations of prior art data representations;

FIG. 2 is a schematic block diagram of a trit encoder, constructed and operative in accordance with a preferred embodiment of the present invention;

FIG. 3A is a schematic block diagram of a trit decoder for decoding trits encoded by the trit encoder of FIG. 2, constructed and operative in accordance with a preferred embodiment of the present invention;

FIG. 3B is a conceptual illustration of bit-level operations performed by the decoder of FIG. 3A on data stored in rows;

FIG. 4 is a schematic block diagram of an associative processing unit (APU), useful in implementing the trit encoder and decoder of FIGS. 2 and 3A;

FIG. 5 is a schematic block diagram of a trit encoder implementing an alternative mapping scheme, constructed and operative in accordance with another preferred embodiment of the present invention;

FIG. 6 is a schematic block diagram of a trit decoder for decoding trits encoded by the trit encoder of FIG. 5, constructed and operative in accordance with another preferred embodiment of the present invention; and

FIG. 7 is a schematic block diagram of a further trit decoder for applications with sparse data.

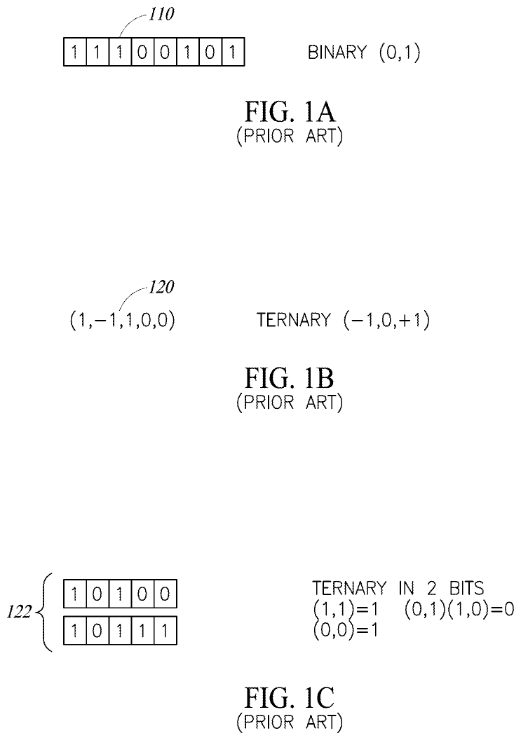

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE PRESENT INVENTION

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

Applicant has realized that a primary obstacle to the efficient use of ternary data in high-performance hardware is the lack of a computationally simple decoding method. The complexity of conventional division and modulo operations in hardware creates a significant performance bottleneck.

Applicant has further realized that an encoding system that uses less than 2 bits/trit is advantageous. The densest form possible is one that uses 1.6 bits/trit. The present invention encodes 1.58 bits/trit (i.e. encoding 5 trits using 8 bits).

Applicant has realized that a decoding system that only uses Boolean operations is extremely efficient. Applicant has further realized that using a base-3 representation to encode the trits makes it possible to decode the encoded trits with Boolean operations.

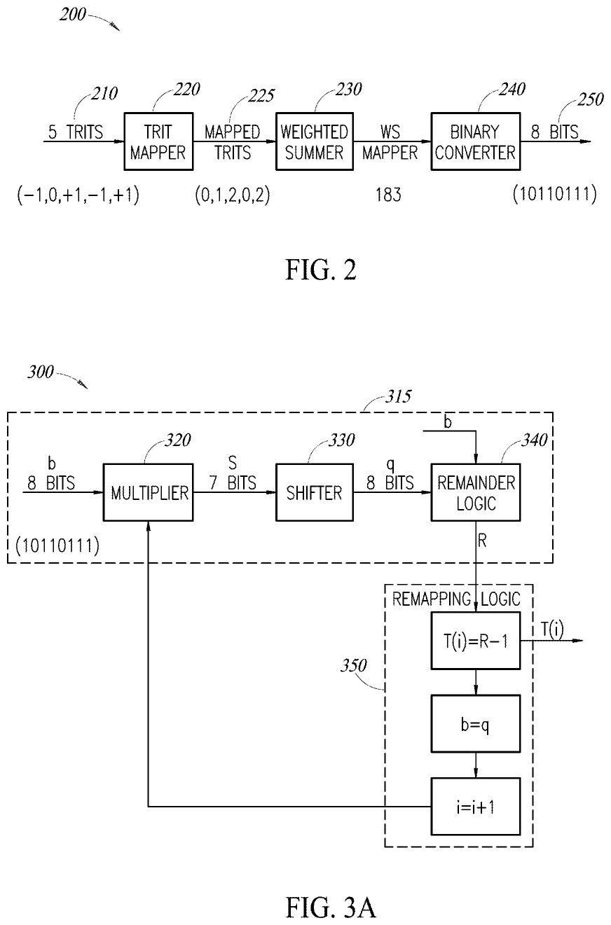

Reference is now made to FIG. 2, a schematic block diagram of a trit encoder 200, constructed and operative in accordance with a preferred embodiment of the present invention. Trit encoder 200 may receive a set of input ternary values 210. Each of the input ternary values 210 may be a value from the set {−1, 0, +1}. In the example in FIG. 2, the input ternary set has five trits to it, of values (−1, 0, +1, −1, +1). Encoder 200 may generate a single encoded integer 250 from the input ternary values 210. In the example, encoded integer 250 has 8 bits to it.

Trit encoder 200 may comprise a trit mapper 220, a weighted summer 230, and a binary converter 240. Trit mapper 220 may receive input ternary values 210 and may map each value to a corresponding non-negative integer. For example, trit mapper 220 may add one (1) to each of the input ternary values 210 to produce a set of five mapped integers 225, each having a value from the set {0, 1, 2}. Mathematically, this is written as:

e(i)=T(i)+1 Equation (1)

where e(i) is a mapped integer value and T(i) is a trit value. In the example in FIG. 2, the five mapped integers 225 are (0,1,2,0,2).

Weighted summer 230 may receive mapped integers 225. Weighted summer 230 may compute a weighted sum WS by treating mapped integers 225 as digits in a base-3 representation. Weighted summer 230 may multiply each of the five mapped integers by a corresponding power of three (i.e. 1, 3, 9, 27, and 81) and may sum the results. Mathematically, this is written as:

$$WS = {\sum }_{i = 0}^{4} {3}^{i} * e [ i ] \qquad Equation ( 2 )$$

For the example of FIG. 2, weighted sum WS is 183.

Binary converter 240 may receive weighted sum WS and may convert it into 8-bit encoded integer 250. Thus, for the example of FIG. 2, weighted sum WS is converted to the 8-bit integer 10110111.

It will be appreciated that there may be a maximum value for weighted sum WS which may fit within a predefined range defined by the number of binary bits. In the example of an 8-bit integer, the maximum value of weighted sum WS is 242, which fits within the range of an 8-bit integer, which is from 0 to 256. This encoding method achieves a compression of five ternary values into eight bits.

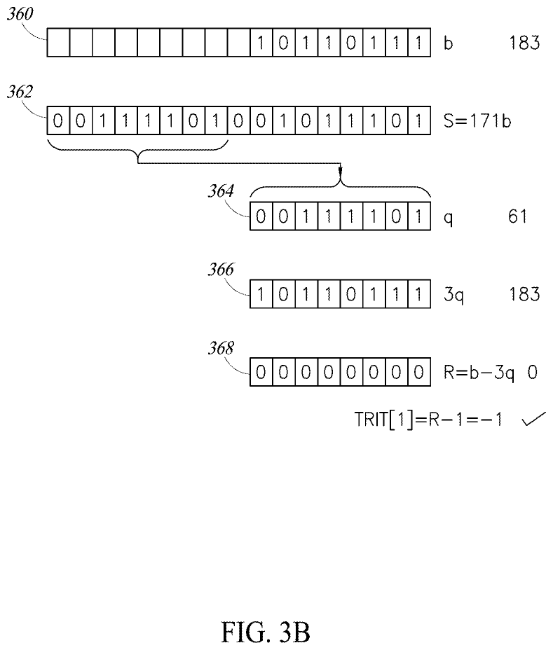

Reference is now made to FIG. 3A, which illustrates a schematic block diagram of a trit decoder 300 for decoding trits encoded by trit encoder 200 of FIG. 2, constructed and operative in accordance with a preferred embodiment of the present invention, and to FIG. 3B, which provides an example of the decoding. Trit decoder 300 may receive an 8-bit encoded integer, here labelled b, and may produce a set of five decoded ternary values T.

Trit decoder 300 may comprise a multiplier 320, a shifter 330, a remainder logic block 340, and a remapping logic block 350. Trit decoder 300 may iteratively process encoded integer b to extract each of the five ternary values T(i).

In a first iteration, multiplier 320 may multiply the value of encoded integer b by a predetermined integer constant K, to produce a 17 bit integer S. Applicant has realized that 171 is the minimal constant guaranteeing exact division for the whole 8-bit byte range of 0 to 256, and thus, K may have a value of 171 (or 0xAB in hex).

Shifter 330 may receive the 17 bit product S from multiplier 320 and may right-shift the multiplied encoded integer by a fixed number of bits to produce a quotient q. For the 8-bit example given hereinabove, shifter 330 may right-shift product S by 9 bits, to give an 8-bit quotient q.

Remainder logic 340 may then calculate an initial remainder R using encoded integer b and 3 times the quotient q. Remainder R will be an integer from the set {0, 1, 2}.

Mathematically, this is written as:

R=b−3q Equation (3)

Remapping logic 350 may receive remainder R and may convert it to a ternary value by subtracting one (1). This may produce the first trit, T(1). For the next iteration, variable b may be replaced by the current value of quotient q, to serve as the new input to multiplier 320 for the next iteration, and the process may be repeated to extract the subsequent ternary values, to recover all five of the decoded ternary values T.

FIG. 3B shows the bit operations for the example of FIG. 3A, for data stored in a few rows of a register. The binary encoded ternary value b (i.e. 10110111) is stored in a first row 360. Multiplier 320 multiplies value b by 171, producing the bit value of 00111101001011101, stored in a second row 362. Shifter 330 then shifts the bits of second row 362 right by 9 bits to produce quotient q (i.e. 00111101), stored in row 364. In decimal terms, q has a value of 61.

Remainder logic 340 then multiplies quotient q by 3 (i.e. 3*61=183), generating a binary value of 10110111, which happens to be the same as the current value of b (i.e. 10110111). Remainder logic 340 subtracts 3q from variable b to produce remainder R, which, in this case, is 0. (R=b−3q=10110111−10110111=0). The trit is then R−1 and thus, the trit T(1) for the first iteration is −1, the first value of the input trit of FIG. 2.

Preparing for the next iteration, variable b is updated to the current value of q and the iteration number i is increased by 1. Thus, new b=q=00111101=61. The process is repeated 4 times, at which point the original byte will be exhausted (i.e. q will be 0 after the last iteration).

It will be appreciated that the multiplication by 171 may be performed as a single operation or via four partial, 2^{x} multiplications (of 1, 2, 8, 32 and 128, since 171=128+32+8+2+1).

This logic may be implemented with any suitable hardware or software. For example, it may be implemented with a Field-Programmable Gate Array (FPGA) or an Application-Specific Integrated Circuit (ASIC) using gate-level primitives, allowing efficient hardware realization without division or modulo units. Such compact logic gate realization is suited for edge Artificial Intelligence (AI), embedded machine learning (ML) systems, and neural network accelerators.

It will be appreciated that modern AI systems are based on neural networks which have large networks of neurons activated by network weights. Such neural networks have, in the past, used either digital weights (multi-bit values) or binary weights (single bit values). Applicant has realized that the present invention may enable AI systems to use ternary weights, due to reduced precision and power requirements.

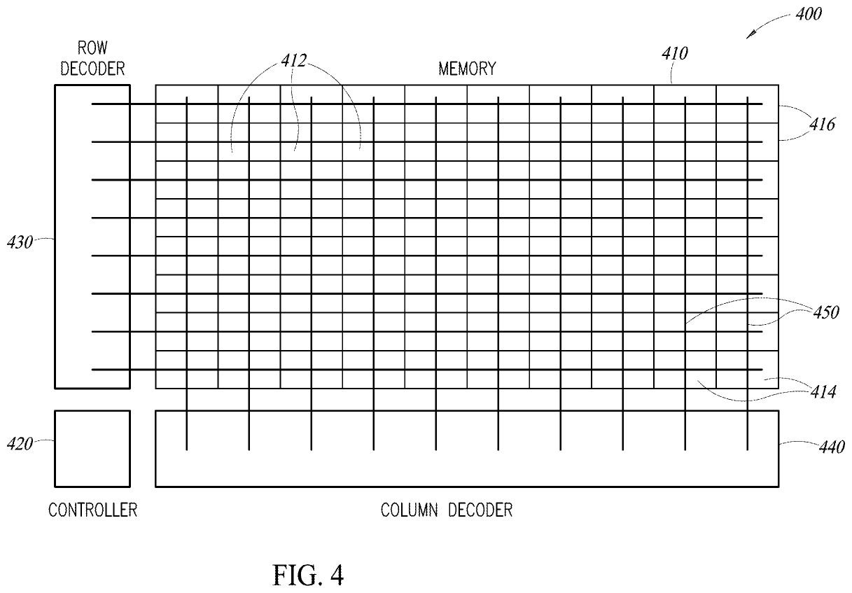

Applicant has realized that trit decoder 300 may be particularly suited for implementation in a parallel computing architecture, such as an associative processing unit (APU). Reference is now made to FIG. 4, a schematic block diagram of an APU 400, such as the Gemini APU, commercially available from Applicant (GSI Technology Inc. of the USA).

APU 400 may comprise an associative memory array 410 controlled by a controller 420, a row decoder 430, and a column decoder 440. Associative memory array 410 may be arranged as a grid of memory cells 412 organized into rows 416 and columns 414. In this architecture, a multi-bit data item, such as an 8-bit encoded integer, may be stored in a single column 414.

APU 400 may further comprise a plurality of bit line processors 450, where each bit line processor 450 is associated with a column 414. Controller 420 may issue commands that cause bit line processors 450 to perform logical and arithmetic operations on the data within their respective columns in a massively parallel fashion. In particular, controller 420 may activate row decoder 430 to activate multiple rows concurrently, and column decoder 440 to activate multiple bit line processors 450. Each bit line processor 450 may sense the results of a Boolean operation on the data of the activated rows in that column.

Referring back to FIG. 3B, the bit-level operations shown therein may be performed within one column 414 of associative memory array 410 (rather than in rows of registers as shown in FIG. 3B). Thus, if there are many encoded integers, such as is the case for the weights of a neural network layer, they may be decoded together, in parallel.

The steps performed by decoder 300 the multiplication, shifting, and subtraction may be decomposed into a series of simple bit-wise logical operations commanded by controller 420, as are described in It will be appreciated that the right shift may be performed in columns 414 by only performing the later steps (those shown in rows 364, 366 and 368) on the upper 8 rows of the column (corresponding to the upper 8 bits of the 17 bit product S).

Bit line processors 450 (of FIG. 4) may execute these operations concurrently on all stored encoded integers. This parallel execution allows for the simultaneous decoding of a vast number of values, achieving extremely high throughput in a fixed, minimal number of clock cycles.

It will be appreciated that the APU may perform the entire five-trit decoding operation in less than 6 cycles. For such an operation, the decoding operation may be overlapped with subsequent MAC fetches so that the decode operation becomes bandwidth-bound rather than latency-bound.

It will be appreciated that decoder 300 may be implemented in a variety of ways. For example, it may operate on 32-bit streams. For these, the encoded integer may be multiplied by the reciprocal OxAAAAAAAB hex value and may then be shifted by a suitable number of bits, such as 33 bits. The result may be four, 8 bit bytes, each to be divided by 3 in parallel.

Another implementation may utilize unbalanced ternary values, having one of (0,1,2) values rather than one of (−1, 0, 1) values. For this implementation, there is no need for the final “−1” bias step.

Another implementation may be with vector GPUs, which are used on edge devices. This implementation may compare favorably with ASTC decoders which often replace the multiply with a 2-KB LUT for throughput. The arithmetic method described hereinabove matches LUT speed while saving cache and is friendlier to edge devices.

Applicant has realized that in many practical applications, such as for storing neural network weights, ternary data may often be sparse (i.e. the value of zero occurs with high frequency). Applicant has further realized that an encoding scheme that maps a ternary zero to a non-zero integer may process all data uniformly. Applicant has realized that a mapping scheme which preserves the zero value may provide a significant computational advantage by enabling a “fast path” for all-zero data blocks, which may allow for enhanced compression and processing speed.

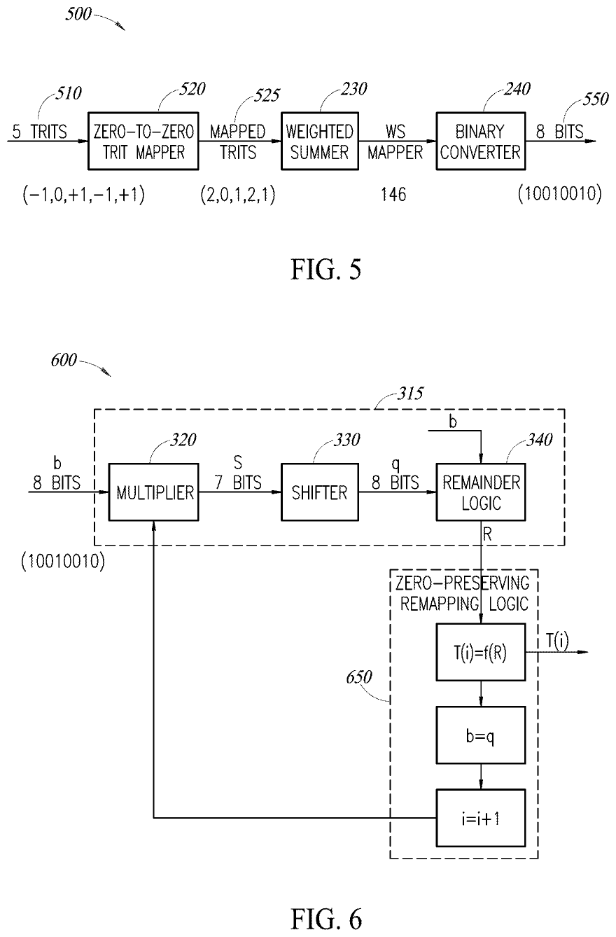

Reference is now made to FIG. 5, which is a schematic block diagram of a trit encoder 500, constructed and operative in accordance with a preferred embodiment of the present invention using this particularly advantageous mapping scheme. Trit encoder 500 may comprise a zero-to-zero trit mapper 520, weighted summer 230, and binary converter 240.

In this embodiment, zero-to-zero trit mapper 520 may receive a set of input ternary values 510, for example, the input ternary values from FIG. 2, which are (−1, 0, +1, −1, +1). Mapper 520 may map these ternary values to a set of mapped integers 525 according to the following rule: a ternary value of 0 maps to a mapped integer of 0, a ternary value of +1 maps to a mapped integer of 1, and a ternary value of −1 maps to a mapped integer of 2.

For the input 510, this may produce the mapped integers 525 of (2, 0, 1, 2, 1).

As in the embodiment of FIG. 2, weighted summer 230 may receive mapped integers 525 and may compute a weighted sum by treating them as digits in a base-3 representation, which, in this embodiment, may produce a weighted sum (WS) of 146. The resulting weighted sum may then be converted by binary converter 240 into an 8-bit encoded integer 550, which has the binary value 10010010.

Reference is now made to FIG. 6, a schematic block diagram of a trit decoder 600 for decoding encoded integer 550 generated by encoder 500. Similar to trit decoder 300, trit decoder 600 may comprise a core arithmetic engine 315 comprising multiplier 320, shifter 330, remainder logic block 340. However, in this embodiment, trit decoder 600 comprises a zero-preserving remapping logic block 650. Decoder 600 may receive encoded integer 146 and may iteratively process it to extract the original ternary values. Core arithmetic engine 315 may produce a sequence of modulo 3 remainders R.

Zero-preserving remapping logic block 650 may receive each remainder R and may apply a corresponding inverse mapping function f(R) to recover the ternary value T(i) according to the following rule:
a remainder of 0 is remapped to a ternary value of 0;
a remainder of 1 is remapped to a ternary value of +1, and
a remainder of 2 is remapped to a ternary value of −1.

Logic block 650 also may manage the iteration by using the quotient q from a preceding iteration as the new input for a subsequent iteration.

The advantage of the mapping scheme of FIGS. 5 and 6 may be most apparent when the input ternary values 510 are all zero. In this special case, the encoded integer 550 is 0 (i.e. 8 zeros).

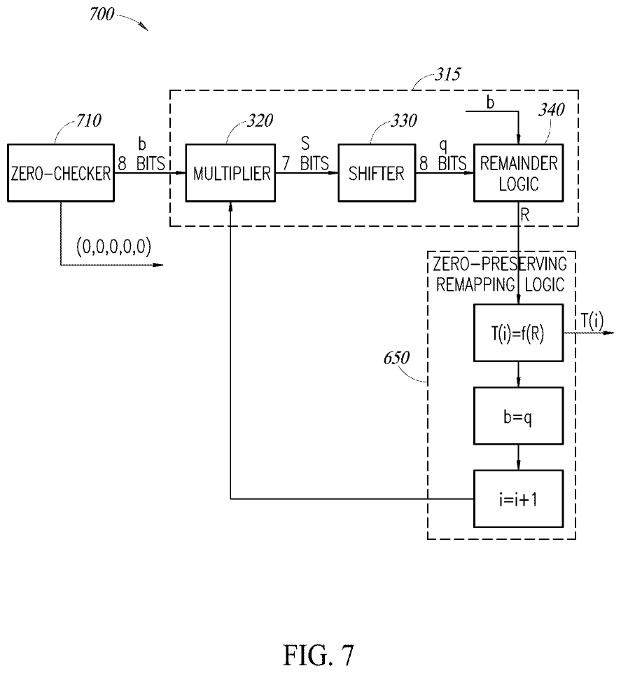

Reference is now briefly made to FIG. 7, which illustrates a trit decoder 700 for applications with sparse data, such as for storing neural network weights. Trit decoder 700 may be similar to trit decoder 600 but may additionally comprise a zero-checker 710 before core arithmetic engine 315.

Zero-checker 710 may perform a check on the received encoded byte; if the byte is zero, then zero-checker 710 may output all five constituent trits with zero values, and may skip the remaining elements of decoder 700.

Moreover, zero-checker 710 may indicate to whatever unit is operating on the output of decoder 700 to skip upcoming multiplication operations or upcoming multiply-accumulate operations. For example, if the unit receiving the output of decoder 700 is a multiplier, the multiplier may provide a zero output when so indicated by zero-checker 710. Alternatively, if the unit receiving the output of decoder 700 is a node of a neural network, the node may skip its operation when so indicated by zero-checker 710.

Specific to the particular structure of APU 400, an additional optimization may be possible. The output of zero-checker 710 may be used in a line compare as a hardware triggered gate, to skip a subsequent downstream processing operation, such as a MAC operation.

It will be appreciated that core arithmetic engine 315 may be agnostic to the specific mapping scheme used during encoding. Core arithmetic engine 315 may be designed to recover the base-3 digits from the weighted sum, regardless of how those digits were originally derived. Consequently, the same arithmetic hardware may correctly process both the encoded integer 183 (from FIG. 2) and the encoded integer 146 (from FIG. 5).

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

What is claimed is:

1. A method for encoding a set of ternary values, each selected from the set {−1, 0, +1}, into an encoded integer having a predefined number of bits, the method comprising:
mapping said ternary values to a set of mapped integers, each mapped integer being a non-negative integer in the set {0, 1, 2}; and
computing a weighted sum of said mapped integers using powers of 3, wherein a final result fits within a predefined byte range defined by said predefined number of bits.

2. The method according to claim 1 and also comprising converting said final result into a binary value.

3. The method according to claim 1 wherein said computing comprises treating said mapped integers as digits in a base-3 representation.

4. The method according to claim 3 wherein said treating comprises multiplying each of said mapped integers by a corresponding power of three to produce multiplied values, and summing said multiplied values.

5. The method according to claim 1 wherein said predefined number of bits is 8 bits, said set of ternary values has 5 values therein, and said predefined byte range is 0 to 256 for said 8 bit integers.

6. A system for encoding a set of ternary values, each selected from the set {−1, 0, +1}, into an encoded integer having a predefined number of bits, the system comprising:
a trit mapper to map each of said ternary values to a set of mapped integers, each mapped integer being a non-negative integer in the set {0, 1, 2};
a weighted summer to compute a weighted sum of said mapped integers by treating the mapped integers as digits in a base-3 representation; and
a binary converter, operatively connected to the weighted summer, configured to convert the weighted sum into the encoded integer.

7. The system of claim 6, wherein said weighted summer is configured to multiply each of said mapped integers by a corresponding power of three and to sum results of said multiplication to compute said weighted sum.

8. The system of claim 6, wherein said predefined number of bits is 8, and wherein said set of ternary values has five values in it, and a byte range is 0 to 256 for said 8 bit integers.

9. An associative processing unit (APU) for parallel encoding a plurality of sets of ternary values, each selected from the set {−1, 0, +1}, into encoded integers having a predefined number of bits, the APU comprising:
an associative memory array having a plurality of bit-line processors therein, said sets of ternary values being stored in columns of said associative memory array, and
a controller configured to issue commands to said APU to implement said trit mapper, said weighted summer, and said binary converter of claim 6 on said bit-line processors via bit-wise logical operations on said sets of ternary values.

10. A method for decoding an encoded binary integer into a set of ternary values, the method comprising:
multiplying said encoded binary integer by a predetermined integer constant, wherein said predetermined integer constant is a minimal constant enabling division within a predefined byte range, to produce a multiplied encoded integer;
right-shifting said multiplied encoded binary integer by a fixed number of bits to produce an iteration version of a quotient;
iteratively computing a modulo 3 remainder of an iteration version of said encoded binary integer by comparing said iteration version of said encoded binary integer to a multiple of 3 of said iteration version of said quotient; and
setting each ternary value to a function of each said modulo 3 remainder.

11. The method according to claim 10 wherein said byte range is 0 to 256 and said predetermined integer constant is 171.

12. The method according to claim 11 wherein said fixed number of bits is 9 bits.

13. The method according to claim 10 wherein said function is subtracting 1.

14. The method according to claim 10 and comprising, for a next iteration, replacing a current said iteration version of said encoded binary integer with a previous iteration version of said quotient.

15. A system for decoding an encoded binary integer into a set of ternary values, the system comprising:
a multiplier to multiply said encoded binary integer by a predetermined integer constant to produce a multiplied encoded integer, wherein said predetermined integer constant is a minimal constant enabling division within a predefined byte range, to produce a multiplied encoded integer;
a shifter to right-shift the multiplied encoded integer by a fixed number of bits to produce an iteration version of a quotient;
a remainder logic block to compute a modulo 3 remainder of an iteration version of said encoded binary integer based on said iteration version of said quotient; and
a remapping logic block to set a ternary value for a current iteration based on said modulo 3 remainder and to use said iteration version of said quotient from a preceding iteration as said iteration version of said encoded binary integer for a subsequent iteration.

16. The system of claim 15, wherein the encoded binary integer is an 8-bit integer, and wherein the predetermined integer constant is 171.

17. The system of claim 16, wherein the fixed number of bits for the right-shift is 9.

18. The system of claim 15, wherein the remapping logic block is configured to set the ternary value by subtracting 1 from the modulo 3 remainder.

19. An associative processing unit (APU) for parallel decoding a set of encoded binary integers into multiple sets of ternary values, the APU comprising:
an associative memory array having a plurality of bit-line processors therein, said sets of ternary values being stored in columns of said associative memory array, and
a controller configured to issue commands to said APU to implement said multiplier, said shifter, said remainder logic block, and said remapping logic block of claim 15 on said bit-line processors via bit-wise logical operations on said sets of ternary values.

20. The system of claim 19, wherein said controller implements said shifter by activating only a subset of rows, said subset of rows corresponding to upper bits of said multiplied encoded integers.

21. The system of claim 15, wherein the remapping logic block is a zero-preserving remapping logic block configured to recover the ternary value according to the following rule:
a remainder of 0 is remapped to a ternary value of 0;
a remainder of 1 is remapped to a ternary value of +1, and
a remainder of 2 is remapped to a ternary value of −1.

22. The system of claim 21, and also comprising a zero-checker before said multiplier to output ternary values of 0 for all trits when said encoded binary integer has a value of 0.
